(19) United States
(12) Patent Application Publication
(10) Pub. No.: US 2006/0240287 A1
(43) Pub. Date: Oct. 26, 2006

(54) Dummy wafer and method for manufacturing thereof

(76) Inventors: Sho Kumagai, Tokyo (JP); Hiroyuki Ishida, Saitama (JP)

Correspondence Address: SUGHRUE MION, PLLC, 2100 PENNSYLVANIA AVENUE, N.W., SUITE 800, WASHINGTON, DC, 20037, US

(21) Appl. No.: 10/561,952

(22) PCT Filed: Jun. 25, 2004
(86) PCT No.: PCT/JP04/08978

§ 371 Date: Jun. 12, 2006

(30) Foreign Application Priority Data
Jun. 27, 2003 (JP) 2003184867
May 12, 2004 (JP) 2004142235

(51) Int. Cl. B32B 9/00; C23C 16/00; B05D 1/12

(52) U.S. Cl. 428/698; 427/180; 427/372.2; 427/248.1

(57) ABSTRACT

A dummy wafer formed by sintering a mixture containing a silicon carbide powder and a non-metallic sintering auxiliary, wherein a coating film layer containing silicon carbide is provided on the surface of the dummy wafer including at least one of either upper and lower main faces of the dummy wafer by the chemical vapor deposition method.

### TECHNICAL FIELD

The present invention relates to a dummy wafer that is used in semiconductor manufacturing processes such as LSI. More particularly, the invention relates to a dummy wafer in which a coating film layer containing silicon carbide is provided on the surface of the dummy wafer.

### BACKGROUND ART

In conventional practices, during treatment of a wafer surface in semiconductor manufacture processes such as LSI, a dummy wafer is used in maintaining constant treatment conditions, improving product yield, and manufacturing a highly integrated device. Wafers constituted entirely of CVD-SiC are widely used as the dummy wafer.

The silicon carbide (SiC) crystal that constitutes such a dummy wafer is formed in columns oriented in the growth direction. For this reason, the growth direction of SiC and the thickness direction of the dummy wafer formed entirely of CVD-SiC coincide with each other, making such a dummy wafer prone to warpage.

On the other hand, loading a device manufacturing apparatus with wafers is carried out by automatic transportation with a robot that is designed on the basis of a standard size of silicon wafers, so that warpage of dummy wafers is liable to cause transportation troubles.

To meet with this, the aforementioned problem of warpage has been solved by replacing the dummy wafer with a dummy wafer (hereafter also referred to as “PB-S”) formed by sintering a mixture containing a silicon carbide powder and a non-metallic sintering auxiliary (See, for example, Patent Document 1.).

However, in using PB-S as a monitor wafer (monitor of film thickness and particles), a further problem to be improved has been raised in that a measurement error occurs due to pores that are present on the surface thereof.

Patent Document 1: Japanese Patent Application Laid-Open No. 10-163079

### DISCLOSURE OF THE INVENTION

For this reason, there is a demand for a dummy wafer with little warpage and with no pores on the surface. Also, there is a demand for a dummy wafer that can be used for certain specific purposes. Namely, the present invention relates to the items described below.

(1) A dummy wafer formed by sintering a mixture containing a silicon carbide powder and a non-metallic sintering auxiliary, wherein

a coating film layer containing silicon carbide is provided on the surface of the dummy wafer including at least one of either upper and lower main faces of the dummy wafer by the chemical vapor deposition method.

(2) The dummy wafer according to (1), wherein the coating film layer containing silicon carbide is provided on the whole perimeter of the surface of the dummy wafer including the side surface of the dummy wafer.

(3) The dummy wafer according to (1) or (2), wherein the coating film layer has a thickness of 20 μm or more and 70 μm or less, and a surface roughness (Ra) of 10 nm or less.

(4) A method for manufacturing a dummy wafer formed by sintering a mixture containing a silicon carbide powder and a non-metallic sintering auxiliary, wherein

the method for manufacturing a dummy wafer has a step of providing a coating film layer containing silicon carbide with a coating film thickness of 20 μm or more and 70 μm or less on the surface of the dummy wafer including at least one of either upper and lower main faces of the dummy wafer by the chemical vapor deposition method.

(5) The method for manufacturing a dummy wafer according to (4), wherein the coating film thickness of the coating film layer is 20 μm or more and 40 μm or less.

(6) The method for manufacturing a dummy wafer according to (4) or (5), further having a step of polishing the surface of the coating film layer.

(7) The method for manufacturing a dummy wafer according to claim 6, wherein the coating film layer after polishing the surface has a thickness of 20 μm or more and 70 μm or less, and a surface roughness (Ra) of 10 nm or less.

(8) The dummy wafer according to any one of (1) to (3), wherein the dummy wafer is for a monitor wafer.

### BEST MODES FOR CARRYING OUT THE INVENTION

As a result of eager studies, the inventors of the present invention have found out that the aforementioned problems can be solved by providing a coating film layer containing silicon carbide on the surface of a dummy wafer that has been formed by sintering a mixture containing a silicon carbide powder and a non-metallic sintering auxiliary.

Hereafter, the present invention will be described by raising embodiments of the invention, however, the invention is not limited by the following embodiments.

A dummy wafer as an embodiment of the invention is manufactured by a production method having: a step of obtaining a silicon carbide sintered body by sintering a mixture containing a silicon carbide powder and a non-metallic sintering auxiliary; a step of obtaining a dummy wafer by performing processing and polishing on the obtained silicon carbide sintered body; a CVD treatment step of forming a SiC coating film on the surface of the obtained dummy wafer by the chemical vapor deposition method (CVD); and a step of performing a polishing treatment on the surface of the dummy wafer that has been subjected to the CVD treatment. Hereafter, description will be made for each step.

(Raw Materials)

The silicon carbide powder used as the raw material of a sintered silicon carbide dummy wafer of the embodiment of the present invention includes an α type powder, β type powder, amorphous powder and mixtures thereof and the like, and particularly, a β type silicon carbide powder is suitably used. The grade of this β type silicon carbide powder is not particularly restricted, and for example, generally marketed β type silicon carbide powders can be used. It is preferable that the particle size of this silicon carbide powder is smaller from the stand point of increase in density, and it is preferably from about 0.01 to 5 μm, further preferably from about 0.05 to 3 μm. When the particle size is less than 0.01 μm, handling intreating processes such as measurement, mixing and the like is difficult, an when over 5 μm, its specific surface area becomes smaller, namely, contact area with adjacent powders becomes smaller, and increase in density is difficult, undesirably.

As a suitable embodiment of a silicon carbide powder, those having a particle size of 0.05 to 1 μm, a specific surface area of 5 m²/g or more, a free carbon content of 1% or less and an oxygen content of 1% or less are suitably used. The particle size distribution of a silicon carbide powder used is not particularly restricted, and that having two or more maximum values can also be used, from the standpoints of increase in the filling density of a powder and the reactivity of a silicon carbide, in producing a sintered silicon carbide dummy wafer.

For obtaining a sintered silicon carbide dummy wafer of high density, it is advantageous to use a silicon carbide powder of high density, as a raw material silicon carbide powder.

A silicon carbide powder of high density can be obtained by a production method comprising a calcination process in which a silicon source containing at least one or more liquid silicon compounds, a carbon source containing at least one or more liquid organic compounds producing carbon by heating, and a polymerization or cross-linking catalyst are uniformly mixed to obtain a solid which is then calcinated under a non-oxidation atmosphere. The silicon source containing liquid silicon compounds, for example, a liquid silicon compound can also be used together with a solid silicon compound.

As the silicon compound used for production of a silicon carbide powder of high purity (hereinafter, appropriately referred to as silicon source), those in liquid form and those in solid form can be used together, however, at least one of them should be selected from liquid compounds. As the liquid compound, polymers of alkoxysilanes (mono-, di-, tri-, tetra-) and tetraalkoxysilanes are used. Of alkoxysilanes, tetraalkoxysilanes are suitably used. Specifically, methoxysilane, ethoxysilane, propoxysilane, butoxysilane and the like are listed, and ethoxysilane is preferable from the standpoint of handling. As the polymer of tetraalkoxisilanes, there are mentioned lower molecular weight polymers (oligomers) having a degree of polymerization of about 2 to 15 and silicic acid polymers having higher polymerization degree in the form of liquid. Mentioned as the solid compound which can be used together with these compounds is silicon oxide. This silicon oxide includes, in the embodiment of the present invention, silica sol (colloidal super fine silica-containing liquid, containing an OH group or alkoxyl group inside), silicon dioxide (silica gel, fine silica, quartz powder) and the like, in addition to SiO.

Of these silicon sources, an oligomer of tetraethoxysilane and a mixture of an oligomer of tetraethoxysilane and fine powdery silica, and the like are suitable from the standpoints of excellent uniformity and excellent handling. As these silicon sources, substances of high purity are used, and those having an initial impurity content of 20 ppm or less are preferable and those having an initial impurity content of 5 ppm or less are further preferable.

As the organic compound producing carbon by heating used in producing a silicon carbide powder of high purity, those in liquid form can be used and additionally, those in liquid form can be used together with those in solid form, and preferable are organic compounds having high actual carbon ratio and being polymerized or cross-linked with a catalyst or by heating, specifically, monomers and prepolymers of resins such as a phenol resin, furan resin, polyimide, polyurethane, polyvinyl alcohol and the like, and in addition, liquid compounds such as cellulose, sucrose, pitch, tar and the like are used, particularly, resol type phenol resins are preferable. Though the purity thereof can be appropriately controlled and selected depending on its object, it is desirable to use an organic compound not containing each metal of 5 ppm or more particularly when a silicon carbide powder of high purity is necessary.

The ratio of carbon to silicon in the embodiment of the present invention (hereinafter, abbreviated as C/Si ratio) is defined by element analysis of a carbide intermediate obtained by carbonizing a mixture at 1000° C. Stoichiometrically, when the C/Si ratio is 3.0, the free carbon content in the produced silicon carbide should be 0%, however, actually, free carbon is generated at lower C/Si ratio, by evaporation of a SiO gas produced simultaneously. It is important to previously determine composition so that the free carbon content in this produced silicon carbide powder is not an amount unsuitable for production of a sintered body and the like. Usually, in calcination at a temperature of 1600° C. or more and a pressure around 1 atm, free carbon can be controlled when the C/Si ratio is regulated to 2.0 to 2.5, and this range can be suitable adopted. When the C/Si ratio is 2.5 or more, free carbon increases remarkably, however, this free carbon has an effect of suppressing grain growth, therefore, the ratio may also be appropriately selected depending on the object of particle formation. In calcination at a lower or higher atmosphere pressure, however, the C/Si ratio for obtaining a pure silicon carbide varies, therefore, in this case, its range is not necessarily restricted to the above-mentioned C/Si ratio.

An action in sintering free carbon is very weak as compared with that of carbon derived from nonmetal-based sintering aid coated on the surface of a silicon carbide powder used in the embodiment of the present invention, therefore, is can be ignored basically.

For obtaining solid prepared by uniformly mixing a silicon source and an organic compound producing carbon by heating in the embodiment of the present invention, it is also effected that a mixture of a silicon source and the organic compound is hardened to give solid, if necessary. As the hardening method, there are mentioned a method of cross-linking by heating, a method of hardening with a hardening catalyst, and a method using electro beam or radiation. The hardening catalyst can be appropriately selected depending on the silicon source, and in the case of a phenol resin and a furan resin, there are used acids such as toluenesulfonic acid, toluenecarboxylic acid, acetic acid, oxalic acid, hydrochloric acid, sulfuric acid and the like, and amines such as hexamine and the like.

This raw material mixed solid is carbonized under heat if necessary. This is conducted by heating the solid in a non-oxidation atmosphere such as nitrogen or argon and the like at 800 to 1000° C. for 30 to 120 minutes.

Further, this carbide is heated in a non-oxidation atmosphere such as argon and the like at 1350° C. or more and 2000° C. or less, to produce a silicon carbide. The calcination temperature and time can be appropriately selected depending on properties such as desired particle size and the like, and for more efficient production, calcination at 1600 to 1900° C. is desirable.

When a powder of higher purity is necessary, impurities can be further removed by performing heating treatment at 2000 to 2100° C. for 5 to 20 minutes in the above-mentioned calcination.

As described above, as the method of obtaining a silicon carbide powder of particularly high purity, there can be used a method of producing a raw material powder described in a method of producing a single crystal filed previously as Japanese Patent Application No. H7-241856 by the present applicant, namely, a method of producing a silicon carbide powder of high purity, characterized in that the method comprises a silicon carbide production process of uniformly mixing one or more compounds selected from tetraalkoxysilanes of high purity and tetraalkoxysilane polymers as a silicon source and an organic compound of high purity producing carbon by heating as a carbon source, and calcinating by heating, under a non-oxidation atmosphere, the resulted mixture to obtain a silicon carbide powder, and a post treatment process in which the resulted silicon carbide powder is maintained at temperatures of 1700° C. or more and less than 2000° C., and heat treatment at temperatures of 2000 to 2100° C. for 5 to 20 minutes is conducted at least once during the above-mentioned temperature maintenance, wherein the above-mentioned two processes are conducted to obtain a silicon carbide powder having a content of each impurity element of 0.5 ppm or less.

As the nonmetal-based sintering aid used in admixture with the above-mentioned silicon carbide powder in producing a sintered silicon carbide of the embodiment of the present invention, a substance referred to as so-called carbon source producing carbon by heating is used, and listed are organic compounds producing carbon by heating or silicon carbide powders (particle size: about 0.01 to 1 μm) having surface coated with these organic compounds, and the former is preferable from the standpoint of its effect.

As the organic compound producing carbon by heating, there are specifically listed coal tar pitch, pitch tar, phenol resins, furan resins, epoxy resins and phenoxy resins, and various saccharides such as monosaccharides such as glucose and the like, oligosaccharides such as sucrose and the like, polysaccharides such as cellulose, starch and the like, having high actual carbon ratio. As these compounds, there are suitably used those in the form of liquid at normal temperature, those dissolved in a solvent, and those having a property of softening or becoming liquid by heating such as thermoplasticity or heat fusion property, for the purpose of uniform mixing with a silicon carbide powder, and of them, suitable are phenol resins giving a molded body of high strength, particularly, resol type phenol resins.

It is believed that this organic compound produces, when heated, an inorganic carbon-based compound such as carbon black and graphite in the system, and this compound acts effectively as a sintering aid. The effect of the embodiment of the present invention cannot be obtained even if carbon black or graphite powder is added as a sintering aid.

In obtaining a mixture of a silicon carbide powder and a non-metallic sintering auxiliary, the non-metallic sintering auxiliary is preferably mixed by being dissolved or dispersed in a solvent. As the solvent, those suitable for a compound to be used as the non-metallic sintering auxiliary, specifically, lower alcohols such as ethyl alcohol, ethyl ether, acetone, or the like can be selected for a phenolic resin which is a suitable organic compound that generates carbon by being heated. Also, as the non-metallic sintering auxiliary and the solvent, it is preferable to use those having a low content of impurities.

When the addition amount of the non-metallic sintering auxiliary mixed with the silicon carbide powder is too small, the sintered body will not have a high density, whereas when the addition amount is too large, it tends to obstruct the attainment of high density because the free carbon contained in the sintered body will increase. For this reason, though depending on the kind of the non-metallic sintering auxiliary to be used, it is preferable that the addition amount is adjusted to be generally 10 wt % or less, preferably 2 to 5 wt %. This amount can be determined by quantitating the amount of silica (silicon oxide) on the surface of the silicon carbide powder in advance with hydrofluoric acid, and stoichiometrically calculating the amount sufficient for reduction thereof.

Here, the addition amount in terms of carbon, as referred to herein, is a value obtained by assuming that the silica quantitated by the above method is reduced with the carbon deriving from the non-metallic sintering auxiliary in accordance with the following chemical reaction formula and considering the residual carbon ratio (ratio by which carbon is produced in the non-metallic sintering auxiliary) after thermal decomposition of the non-metallic sintering auxiliary, or the like.
SiO₂+3C→SiC+2CO

Also, in the silicon carbide sintered body, the sum of the carbon atoms deriving from the silicon carbide and the carbon atoms deriving from the non-metallic sintering auxiliary contained in the silicon carbide sintered body preferably exceeds 30 wt % and is 40 wt % or less. When the content is 30 wt % or less, the ratio of the impurities contained in the sintered body will increase, whereas when the content exceeds 40 wt %, the carbon content will be high to decrease the density of the obtained sintered body, and various characteristics such as the strength and oxidation resistance of the sintered body will be aggravated, so that it is not preferable.

In producing a silicon carbide sintered body, first a silicon carbide powder and a non-metallic sintering auxiliary are uniformly mixed. As described before, a phenolic resin which is a non-metallic sintering auxiliary is dissolved in a solvent such as ethyl alcohol, and is sufficiently mixed with a silicon carbide powder. The mixing can be carried out by known mixing means, for example, with a mixer, a planetary ball mill, or the like. The mixing is preferably carried out for 10 to 30 hours, particularly 16 to 24 hours. After sufficient mixing, the solvent is removed at a temperature that accords with the physical properties of the solvent, for example, at a temperature of 50 to 60° C. in the aforementioned case of ethyl alcohol, to dry the mixture by evaporation, followed by sieving to obtain a source material powder of the mixture. Here, in view of achieving high purity, the materials of the ball mill container and the balls must be synthetic resin that contains metals as little as possible. Also, in drying, a granulation apparatus such as a spray dryer can be used.

The sintering step which is an essential step in the method of manufacturing a dummy wafer is a step of placing a mixture of powders or a molded body of a mixture of the powders obtained in a later-mentioned molding step, in a forming mold for performing hot pressing at a temperature of 2000 to 2400° C. under a pressure of 300 to 700 kgf/cm² in a non-oxidizing atmosphere.

For the forming mold to be used here, it is preferable to use a material such as one made of graphite in a part or the whole of the mold or to allow a polytetrafluoroethylene sheet (trademark name “Teflon Sheet”) or the like to intervene in the mold so that the molded body and the metal part of the mold will not be in direct contact with each other, in view of the purity of the obtained sintered body.

For the pressure of hot pressing, pressurization can be carried out under the condition of 300 to 700 kgf/cm². In particular, when the pressurization is carried out at 400 kgf/cm² or higher, the hot pressing components used herein, for example, dice, punches, and the like must be those having a good pressure resistance.

Here, the sintering step will be described in detail. It is preferable that, before the hot pressing step for producing the sintered body, the impurities are sufficiently removed by heating and raising the temperature under the following conditions to allow complete carbonization of the carbon source, and thereafter the hot pressing treatment under the above condition is carried out.

Namely, the temperature raising step is preferably carried out through the following two stages. First, the inside of the furnace is gradually heated from room temperature to 700° C. under vacuum. Here, when the temperature control of the high-temperature furnace is difficult, the temperature may be raised to 700° C. continuously; however, the temperature is preferably raised gradually from room temperature to 200° C. by setting the inside of the furnace to be 10⁻⁴ torr, and the above temperature is maintained for a predetermined period of time. Thereafter, the temperature is further kept being gradually raised for heating up to 700° C. Further, the temperature around 700° C. is maintained for a predetermined period of time. In this first temperature raising step, decomposition of the adsorbed water and the binder is carried out, and carbonization is carried out by thermal decomposition of carbon sources. As to the period of time for holding the temperature around 200° C. or around 700° C., a suitable range is selected depending on the kind of the binder and the size of the sintered body. Whether the holding time is sufficient or not can be determined by considering the time point at which the decrease in the vacuum degree becomes small to a certain degree. When rapid heating is carried out at this stage, removal of the impurities and carbonization of the carbon sources are not sufficiently carried out, and there is a fear that cracks or holes may be created in the molded body, so that it is not preferable.

By raising one example, regarding a sample of about 5 to 10 g, the pressure is set at 10⁻⁴ torr; the temperature is gradually raised from room temperature to 200° C.; the above temperature is held for about 30 minutes; and thereafter the temperature is further kept being raised gradually to 700° C., or the period of time from room temperature up to 700° C. is about 6 to 10 hours, preferably around 8 hours. Further, it is preferable that the temperature around 700° C. is held for about 2 to 5 hours.

In vacuum, the temperature is further raised from 700° C. up to 1500° C. in 6 to 9 hours if under the above condition, and the temperature of 1500° C. is held for about 1 to 5 hours. It seems that, in this step, the reduction reaction of silicon dioxide and silicon oxide takes place. In order to remove the oxygen bonded to silicon, it is important that this reduction reaction is sufficiently completed, and it is necessary that the period of time for holding the temperature of 1500° C. is until the generation of carbon monoxide, which is a by-product of this reduction reaction, is completed, namely, the temperature is held until the decrease of the vacuum degree becomes small and recovers to the vacuum degree of around 1300° C. which is the temperature before starting the reduction reaction. By this reduction reaction in this second temperature raising step, the silicon dioxide that obstructs the densification to cause large granule growth by adhering to the silicon carbide powder surface is removed. The gas containing SiO and CO generated during this reduction reaction is accompanied by impurity elements. Since these generated gases are continually discharged to a reaction furnace by a vacuum pump to be removed, it is preferable that this temperature holding is carried out sufficiently also in view of achieving a high purity.

After these temperature raising steps are ended, high-pressure hot-pressing is preferably carried out. When the temperature rises to a temperature higher than 1500° C., the sintering starts. At this time point, pressurization is started considering 300 to about 700 kgf/cm² as a standard in order to suppress abnormal granule growth. Thereafter, an inert gas is introduced in order to set the inside of the furnace to be in a non-oxidizing atmosphere. As this inert gas, nitrogen, argon, or the like is used, however, it is preferable to use argon gas because argon is non-reactive even at a high temperature.

After the inside of the furnace is set to be in a non-oxidizing atmosphere, heating and pressing are carried out so that the temperature will be 2000 to 2400° C. and the pressure will be 300 to 700 kgf/cm². The pressure at the pressing time can be selected in accordance with the particle size of the source material powder. When the particle size of the source material powder is small, a suitable sintered body can be obtained even if the pressure at the time of pressing is comparatively small. Also, here, the temperature raising from 1500° C. to the maximum temperature of 2000 to 2400° C. is carried out in 2 to 4 hours. The sintering rapidly proceeds at 1850 to 1900° C. Further, this maximum temperature is held for 1 to 3 hours to complete the sintering.

Here, when the maximum temperature is lower than 2000° C., the attainment of high density will be insufficient, whereas when the maximum temperature exceeds 2400° C., there is a fear that the molded body source material will be sublimed (decomposed), so that it is not preferable. Also, when the pressurization condition is below 500 kgf/cm², the attainment of high density will be insufficient, whereas when the pressurization condition exceeds 700 kgf/cm², it will be a cause of the destruction of the forming mold such as a graphite mold, so that it is not preferable in view of production efficiency.

In this sintering step also, the heat insulating material or the like of the graphite mold or the heating furnace to be used here is preferably made of a graphite material of high purity in view of holding the purity of the obtained sintered body. As the graphite material, those being treated to have a high purity are used. Specifically, those being sufficiently baked in advance at a temperature of 2500° C. or above and causing no generation of impurities at the sintering temperature are desirable. Further, for the inert gas to be used, it is preferable to use highly pure products with little impurities.

By performing the above sintering steps, a silicon carbide sintered body having excellent characteristics is obtained. In view of attaining high density of the sintered body that is finally obtained, a molding step described in the following may be carried out prior to this sintering step. Hereafter, a molding step that can be carried out prior to this sintering step will be described. Here, the molding step is a step of placing in a mold a source material powder obtained by uniformly mixing a silicon carbide powder and a carbon source, and preparing a molded body in advance by heating and pressing the source material powder in a temperature range of 80 to 300° C. for 5 to 60 minutes. Here, the filling of the mold with the source material powder is preferably carried out as densely as possible in view of attaining high density of the final sintered body. When this molding step is carried out, a bulky powder can be made compact in advance in filling with a sample for hot pressing, so that it will be easier to produce a molded body having a high density or a molded body having a large thickness by repetition.

The introduced source material powder is pressed at a heating temperature within a range from 80 to 300° C., preferably from 120 to 140° C., and under a pressure within a range from 60 to 100 kgf/cm² so that the density of the source material powder will be 1.5 g/cm³ or higher, preferably 1.9 g/cm³ or higher, and the pressurized state is maintained for 5 to 60 minutes, preferably 20 to 40 minutes to obtain a molded body made of the source material powder. Here, regarding the density of the molded body, the smaller the average particle size of the powder is, the more difficult it will be to attain high density. Therefore, in order to attain a high density, it is preferable to adopt a method such as vibration filling in placing a source material powder in the forming mold. Specifically, it is more preferable that, with regard to a powder having an average particle size of about 1 μm, the density is 1.8 g/cm³ or higher, and with regard to a powder having an average particle size of about 0.5 μm, the density is 1.5 g/cm³ or higher. When the density is less than 1.5 g/cm³ or 1.8 g/cm³ in the respective particle sizes, it will be difficult to attain high density of the sintered body that is finally obtained.

This molded body can be subjected to a grinding process in advance in order to be suitable for the hot-pressing mold to be used prior to being subjected to the next sintering step. This molded body is subjected to the step of placing and hot-pressing in a forming mold at the above temperature of 2000 to 2400° C. and under a pressure of 300 to 700 kgf/cm² in a non-oxidizing atmosphere, i.e. the sintering step, to obtain a silicon carbide sintered body having a high density and a high purity.

The silicon carbide sintered body created by the above procedure is made to have a sufficiently high density, and has a density of 2.9 g/cm³ or more. When the density of the obtained sintered body is less than 2.9 g/cm³, the mechanical characteristics such as flexural strength and breakage strength as well as the electrical physical properties decrease, and also the particles increase to aggravate the contamination property, so that it is not preferable. The density of the silicon carbide sintered body is more preferably 3.0 g/cm³ or higher.

Also, when the obtained sintered body is a porous body, it will have disadvantages in the physical properties such as inferiority in the heat resistance, oxidation resistance, chemical resistance, and mechanical strength, difficulty in cleaning, generation of minute cracks to make minute pieces become a contaminating substance, and having a gas transmittance property, thereby also raising a problem of limited use.

The total content of the impurity elements of the silicon carbide sintered body obtained as described above is 5 ppm or less, preferably 3 ppm or less, more preferably 1 ppm or less. In view of application to the field of semiconductor industry, the content of these impurities by these chemical analyses has a meaning only as a reference value. Practically speaking, the evaluation will be different depending on whether the impurities are uniformly distributed or locally present. Therefore, those skilled in the art are generally evaluating to what degree the impurities contaminate a wafer under a predetermined heating condition by various means with the use of a practical apparatus. Here, by a production method including a sintering step of further sintering in a non-oxidizing atmosphere after heating and carbonizing in a non-oxidizing atmosphere a solid substance obtained by uniformly mixing a silicon compound in a liquid form, an organic compound in a liquid form that generates carbon by being heated, and a polymerizing or cross-linking catalyst, the total content of the impurity elements contained in a silicon carbide sintered body can be reduced to 1 ppm or lower. Also, in doing this, as the above material, a substance having a suitable purity needs to be selected in accordance with the desired purity of the obtained silicon carbide sintered body. Here, the impurity elements refer to the elements belonging to the group I to group XVI elements in the periodic table of the revised IUPAC inorganic chemistry nomenclature of the year 1989 and having an atomic number of 3 or more, excluding the elements having an atomic number of 6 to 8 and 14.

In addition, preferable physical properties of the above silicon carbide sintered body are studied. For example, it is preferable that the flexural strength at room temperature is 50.0 to 65.0 kgf/mm²; the flexural strength at 1500° C. is 55.0 to 80.0 kgf/mm²; Young's modulus is 3.5×10⁴ to 4.5×10⁴; the Vickers hardness is 2000 kgf/mm² or more; Poisson's ratio is 0.14 to 0.21; the thermal expansion coefficient is 3.8×10⁻⁶ to 4.2×10⁻⁶ (° C.⁻¹); the thermal conductivity is 150 W/m·k or more; the specific heat is 0.15 to 0.18 cal/g·° C.; the heat shock resistance is 500 to 700 ΔT° C.; and the specific resistance is 1 Ω·cm or less.

(Dummy Wafer)

The silicon carbide sintered body obtained by the above-described production method is subjected to treatments such as processing, polishing, and cleaning to obtain a dummy wafer. The dummy wafer can be produced by forming a cylindrical sample (sintered body) by hot pressing or the like and subjecting this to a slicing process in a radial direction. As the processing method therefor, an electric discharging process is suitably used.

As one example of a dummy wafer, a dummy wafer having a diameter of 100 to 400 mm and a thickness of 0.5 to 1.0 mm can be produced and, as the surface roughness of the wafer, the center line average roughness (Ra) can be adjusted within a range of 0.01 to 10 μm by polishing depending on the usage.

In the above-described production method, there is no particular limitation to the production apparatus and the like as long as the above heating conditions can be satisfied. By considering the pressure resistance of the mold for sintering, the inside of a known heating furnace or a reaction apparatus can be used.

The respective purities of the silicon carbide powder constituting a source material powder, the silicon source and the carbon source for producing the source material powder, and further the inert gas used for providing a non-oxidizing atmosphere are preferably such that each impurity element content is 5 ppm or below, however, the purities are not limited to this as long as the purities are within an allowance range for purification in the heating and sintering steps. Also, here, the impurity elements refer to the elements belonging to the group I to group XVI elements in the periodic table of the revised IUPAC inorganic chemistry nomenclature of the year 1989 and having an atomic number of 3 or more, excluding the elements having an atomic number of 6 to 8 and 14.

(CVD Process)

After the thickness and the surface roughness of the dummy wafer obtained as described above are adjusted, a coating film layer containing silicon carbide is provided on a surface of the dummy wafer by chemical vapor deposition method (CVD). By performing such a CVD process, one can obtain a dummy wafer with no pores on the surface. In this case, the above coating film layer is provided on a surface including at least one of either upper and lower main faces of the dummy wafer. In view of eliminating the restriction of usage, the coating film layer is preferably provided on both of the upper and lower main faces of the dummy wafer, and more preferably provided on the whole perimeter of the surface of the dummy wafer including the side surface of the dummy wafer.

After the coating film layer is provided on the surface of the dummy wafer, the coating film layer is polished under a polishing condition that accords with the usage of the dummy wafer. Here, the total thickness of the dummy wafer must be a value according to the standard size of a Si wafer. In this case, when the coating film layer is too thick, one has to make the base material thin and, as a result, warpage is likely to be generated in the dummy wafer. For this reason, in order to prevent warpage of the dummy wafer, the coating film layer is preferably made thin to a degree such that the base material may not be exposed during the polishing step while maintaining the thickness of the base material to be thick to a certain extent.

Specifically, it is convenient that the thickness of the coating film layer is adjusted so that the thickness of the coating film layer after polishing the coating film layer will be 70 μm at the maximum. This is because, when the thickness of the coating film layer exceeds 70 μm, the base material thickness must be made thin, so that it tends to generate warpage. It is preferable to adjust the thickness of the coating film layer to be 20 μm or more and 70 μm or less, further preferably 20 μm or more and 40 μm or less, by controlling the CVD processing conditions and the conditions for polishing the coating film layer during this period. Also, it is convenient that the surface roughness (Ra) is set to be 10 nm or less, preferably 1 nm or less. Here, it is especially preferable that the lower limit value of the surface roughness (Ra) is 0 nm, however, the lower limit value is about 0.2 nm.

In the manner shown above, a dummy wafer having an extremely high purity is obtained. Also, by adjusting the polishing condition after the CVD process, a highly pure dummy wafer that can be used also as a monitor wafer is obtained.

### EXAMPLES

Hereafter, the present invention will be specifically described by raising Examples, however, the invention is not limited to the present Examples as long as the gist of the present invention is not exceeded.

### Example 1

Production of Highly Pure Silicon Carbide Powder

A uniform resinous solid substance was obtained by mixing 680 g of highly pure ethyl silicate oligomer having a silica content of 40% and 305 g of highly pure liquid resol-type phenolic resin having a water content of 20%, and adding 137 g of a 28% aqueous solution of highly pure toluenesulfonic acid as a catalyst, followed by curing and drying. This was carbonized for one hour at 900° C. in a nitrogen atmosphere. The C/Si of the obtained carbide was 2.4 as a result of element analysis. A container made of carbon was loaded with 400 g of this carbide. After the temperature was raised to 1850° C. in an argon atmosphere and maintained for 10 minutes, the temperature was raised to 2050° C. and maintained for 5 minutes, followed by lowering the temperature to obtain a powder having an average particle size of 1.3 μm. The impurity content was 0.5 ppm or below for each element.

Production of a Molded Body

In a planetary ball mill, 141 g of the highly pure silicon carbide powder obtained by the above-described method and a solution obtained by dissolving 9 g of highly pure liquid resol-type phenolic resin having a water content of 20% in 200 g of ethanol were agitated for 18 hours and sufficiently mixed. Thereafter, the resultant was heated to 50 to 60° C. to evaporate ethanol for drying, followed by sieving with a sieve of 500 μm to obtain a uniform silicon carbide source material powder. A mold was loaded with 15 g of this source material powder, followed by pressing at 130° C. for 20 minutes to obtain a cylindrical molded body having a density of 2.1 g/cm³, an outer diameter of about 200 mm, and a thickness of about 100 mm.

Production of Sintered Body

This molded body was put into a mold made of graphite, and hot-pressing was carried out under the following conditions. (Conditions for sintering step) The temperature was raised from room temperature to 700° C. in 6 hours under a vacuum condition of 10⁻⁵ to 10⁻⁴ torr, and this temperature was maintained for 5 hours. (First temperature raising step) The temperature was raised from 700° C. to 1200° C. in 3 hours under a vacuum condition, and further the temperature was raised from 1200° C. to 1500° C. in 3 hours and this temperature was maintained for 1 hour. (Second temperature raising step) Further, the molded body was pressed with a pressure of 500 kgf/cm², and the temperature was raised from 1500° C. to 2200° C. in 3 hours in an argon atmosphere, and this temperature was maintained for 1 hour. (Hot-pressing step) The obtained sintered body had a density of 3.15 g/cm³, a Vickers hardness of 2600 kgf/mm², and a specific electric resistance of 0.2 Ω·cm.

Also, physical properties were measured in detail on the sintered body obtained in Example 1. As a result of this, as characteristics other than the above, the flexural strength at room temperature was 50.0 kgf/mm²; the flexural strength at 1500° C. was 50.0 kgf/mm²; Young's modulus was 4.1×10⁴; Poisson's ratio was 0.15; the thermal expansion coefficient was 3.9×10⁻⁶° C.⁻¹);

the thermal conductivity was 200 W/m-k or more; the specific heat was 0.16 cal/g·° C.; and the heat shock resistance was 530 ΔT° C., thereby confirming that all of the aforementioned preferable physical properties are satisfied.

Production of Dummy Wafer (Two-Sided Coating)

The sintered body obtained as shown above was subjected to a slicing process with an electric discharge processing machine, and the cut surface was polished with a polishing machine to obtain a dummy wafer having a diameter of 200 mm and a thickness of 0.6 mm. During that time, the upper and lower main faces of the dummy wafer were adjusted to have a predetermined surface roughness (Ra).

CVD Process

The obtained dummy wafer was subjected to a CVD process to form a silicon carbide coating film layer on the upper and lower main faces of the dummy wafer. Then, by polishing the coating film layer, a two-sided coated dummy wafer was obtained having a coating film thickness of 42 μm, surface roughness (Ra)=0.56 nm, maximum unevenness value (Ry)=28 nm after polishing.

### Example 2

Production of Highly Pure Silicon Carbide Powder

A uniform resinous solid substance was obtained by mixing 680 g of highly pure ethyl silicate oligomer having a silica content of 40% and 305 g of highly pure liquid resol-phenolic resin having a water content of 20%, and adding 137 g of a 28% aqueous solution of highly pure toluenesulfonic acid as a catalyst, followed by curing and drying. This was carbonized for one hour at 900° C. in a nitrogen atmosphere. The C/Si of the obtained carbide was 2.4 as a result of element analysis. A container made of carbon was loaded with 400 g of this carbide. After the temperature was raised to 1850° C. in an argon atmosphere and maintained for 10 minutes, the temperature was raised to 2050° C. and maintained for 5 minutes, followed by lowering the temperature to obtain a powder having an average particle size of 1.3 μm. The impurity content was 0.5 ppm or below for each element.

Production of a Molded Body

In a planetary ball mill, 141 g of the highly pure silicon carbide powder obtained by the above-described method and a solution obtained by dissolving 9 g of highly pure liquid resol-phenolic resin having a water content of 20% in 200 g of ethanol were agitated for 18 hours and sufficiently mixed. Thereafter, the resultant was heated to 50 to 60° C. to evaporate ethanol for drying, followed by sieving with a sieve of 500 μm to obtain a uniform silicon carbide source material powder. A mold was loaded with 15 g of this source material powder, followed by pressing at 130° C. for 20 minutes to obtain a cylindrical molded body having a density of 2.1 g/cm³, an outer diameter of about 200 mm, and a thickness of about 100 mm.

Production of Sintered Body

This molded body was put into a mold made of graphite, and hot-pressing was carried out under the following conditions. (Conditions for sintering step) The temperature was raised from room temperature to 700° C. in 6 hours under a vacuum condition of 10⁻⁵ to 10⁻⁴ torr, and this temperature was maintained for 5 hours. (First temperature raising step) The temperature was raised from 700° C. to 1200° C. in 3 hours under a vacuum condition, and further the temperature was raised from 1200° C. to 1500° C. in 3 hours and this temperature was maintained for 1 hour. (Second temperature raising step) Further, the molded body was pressed with a pressure of 500 kgf/cm², and the temperature was raised from 1500° C. to 2200° C. in 3 hours in an argon atmosphere, and this temperature was maintained for 1 hour. (Hot-pressing step) The obtained sintered body had a density of 3.15 g/cm³, a Vickers hardness of 2600 kgf/mm², and a specific electric resistance of 0.2 Ω·cm.

Also, physical properties were measured in detail on the sintered body obtained in Example 2. As a result of this, as characteristics other than the above, the flexural strength at room temperature was 50.0 kgf/mm²; the flexural strength at 1500° C. was 50.0 kgf/mm²; Young's modulus was 4.1×10⁴; Poisson's ratio was 0.15; the thermal expansion coefficient was 3.9×10⁻⁶° C.⁻¹); the thermal conductivity was 200 W/m·k or more; the specific heat was 0.16 cal/g·° C.; and the heat shock resistance was 530 ΔT° C., thereby confirming that all of the aforementioned preferable physical properties are satisfied.

Production of Dummy Wafer (Whole Perimeter Coating)

The sintered body obtained as shown above was subjected to a slicing process with an electric discharge processing machine, and the cut surface was polished with a polishing machine to obtain a dummy wafer having a diameter of 200 mm and a thickness of 0.6 mm. During that time, the upper and lower main faces and the side surface of the dummy wafer were adjusted to have a predetermined surface roughness (Ra).

CVD Process

The obtained dummy wafer was subjected to a CVD process to form a silicon carbide coating film layer on the upper and lower main faces and the side surface of the dummy wafer. Then, by polishing the coating film layer, a whole-perimeter-coated dummy wafer was obtained having a coating film thickness of 38 μm, surface roughness (Ra)=0.48 nm, maximum unevenness value (Ry)=22 nm after polishing.

(Evaluation)

(1) Warpage Property

The warpage property of the obtained dummy wafers of Examples 1 and 2 was observed under the following experimental conditions, with the result that all had a warpage of less than 50 μm.

Measuring apparatus: trade name “3D CNC image measuring machine QUICK VISION” manufactured by Mitsutoyo Co., Ltd.

Evaluation conditions: number of measured points was 19, JIS b 0601

(2) Evaluation of Surface Roughness and Presence or Absence of Unevenness

Regarding the surface roughness of the obtained dummy wafers of Examples 1 and 2, unevenness was confirmed under the following experimental conditions. As a result of this, it was confirmed that, on the surface, there were no pores such as seen in the sintered body; the surface roughness (Ra) was less than 10 nm; and the maximum unevenness value (Ry) was less than 50 nm.

Measuring apparatus: trade name “NV2000 Scanning-type Probe Microscope” manufactured by Olympus Optical Industry Co., Ltd.

Field of view for measurement: 10 μm×10 μm with magnifications of 500 times and 5000 times

Measurement Conditions: JIS-B-0621

From the above experimental results, it has been found out that the present Examples provide a dummy wafer with little warpage and with no pores on the surface. Also, it has been found out that the present Examples provide a dummy wafer which is suitable for a monitor wafer.

### INDUSTRIAL APPLICABILITY

A dummy wafer with little warpage and with no pores on the surface is provided. A dummy wafer usable as a monitor wafer is provided in a suitable mode.

1. A dummy wafer formed by sintering a mixture containing a silicon carbide powder and a non-metallic sintering auxiliary, wherein
a coating film layer containing silicon carbide is provided on the surface of the dummy wafer including at least one of either upper and lower main faces of the dummy wafer by the chemical vapor deposition method.

2. The dummy wafer according to claim 1, wherein the coating film layer containing silicon carbide is provided on the whole perimeter of the surface of the dummy wafer including the side surface of the dummy wafer.

3. The dummy wafer according to claim 1, wherein the coating film layer has a thickness of 20 μm or more and 70 μm or less, and a surface roughness (Ra) of 10 nm or less.

4. A method for manufacturing a dummy wafer formed by sintering a mixture containing a silicon carbide powder and a non-metallic sintering auxiliary, wherein
the method for manufacturing a dummy wafer has a step of providing a coating film layer containing silicon carbide with a coating film thickness of 20 μm or more and 70 μm or less on the surface of the dummy wafer including at least one of either upper and lower main faces of the dummy wafer by the chemical vapor deposition method.

5. The method for manufacturing a dummy wafer according to claim 4, wherein the coating film thickness of the coating film layer is 20 μm or more and 40 μm or less.

6. The method for manufacturing a dummy wafer according to claim 4, further having a step of polishing the surface of the coating film layer.

7. The method for manufacturing a dummy wafer according to claim 6, wherein the coating film layer after polishing the surface has a thickness of 20 μm or more and 70 μm or less, and a surface roughness (Ra) of 10 nm or less.

8. The dummy wafer according to claim 1, wherein the dummy wafer is for a monitor wafer.
